(19) United States
(12) Patent Application Publication
(10) Pub. No.: US 2013/0125966 A1
(43) Pub. Date: May 23, 2013

(54) SOLAR CELL WITH PHOTON COLLECTING MEANS

(71) Applicant: William N. Reining, Cross Plains, WI (US)

(72) Inventor: William N. Reining, Cross Plains, WI (US)

(21) Appl. No.: 13/807,263

(22) PCT Filed: Jun. 30, 2011
(86) PCT No.: PCT/US2011/042585

§ 371 Date: Jan. 29, 2013

Related U.S. Application Data
(60) Provisional application No. 61/360,253, filed on Jun. 30, 2010.

(51) Int. Cl. H01L 31/065

(52) U.S. Cl. CPC H01L 31/065
USPC 136/255

(57) ABSTRACT

A solar cell is disclosed. The solar cell includes a p-type doped semiconductor material and an n-type doped semiconductor material laterally adjacent to the p-type material. The p-type material and n-type material form a stripped structure with finite depth, and form a vertically structured diode at the junction of the p-type material and n-type material. The vertically structured diode has its depth determined by a multiple of an electromagnetic skin depth of at least one of the p-type material or n-type material, and a width of a depletion layer is controlled by a doping concentration of the p-type and n-type material. A solar cell having a refractory material forming an optical element provided on a sun facing surface of the solar cell and adapted to direct photons to a depletion region of a vertically structured photodiode is also disclosed.

### CROSS-REFERENCE TO RELATED APPLICATIONS

This application claims priority to U.S. Provisional Patent Application Ser. No. 61/360,253, filed Jun. 30, 2010, entitled “SOLAR CELL” the contents of which is incorporated herein by reference in its entirety.

### FIELD

The present invention relates to a solar cell. The present invention more specifically relates to solar cells having one or more p-n vertical junctions forming a photodiode and/or a light sensitive area formed by an array of optical elements capable of changing the direction of incoming radiation to further direct it toward the junctions.

### BACKGROUND

Solar cells convert at least a portion of available light into electrical energy. Solar or photovoltaic cells are semiconductor devices having p-n junctions and/or depletion regions that convert radiant energy of sunlight into electrical energy. Referring to FIG. 1, typical cells include a layered structure, including two types of impure or doped silicon material. These materials may be stacked in any order. Typically a p-type silicon is positioned above an n-type silicon. This can be a single silicon material doped in different regions. The p-type silicon and n-type silicon interface forms a junction. The term “junction” refers to the boundary interface where the two regions of the semiconductor meet. The junction and its depletion or space charge region forms the core of the device and is typically a region where the conversion of photons to photoelectrons occurs. As indicated, p-n junctions may be created in a single crystal of a semiconductor by doping the crystal with p and n type material, such as for example by ion implantation, diffusion of dopants, or by epitaxy. It is also contemplated the materials can be separately formed and assembled.

A depletion region forms instantaneously across a p-n junction. The depletion region, also called depletion layer, depletion zone, junction region or the space charge region, is an insulating region within the conductive, doped semiconductor material where the mobile charge carriers have diffused away leaving none to carry a current, or have been forced away by an electric field. Typically, the only elements left in the depletion region are ionized donor or acceptor impurities.

The typical solar cell has a lateral p-n junction and/or depletion region that is parallel or planar to the face or top surface (i.e., the sun facing surface) of the semiconductor material. The layered structure of a solar cell also includes electrical contact layers which allow electric current to flow out of and into the cell. Often, a thin metal electrical contact or a metal grid forms the electrical contact on the face of the solar cell. In addition to the thin metal contact, an insulator, such as glass, is provided on a top surface of the p-type material. Photovoltaic modules (solar cells electrically connected and encapsulated) often have a sheet of glass or a similar material on the front or sun-facing side, allowing light to pass while protecting the semiconductor wafers from abrasion and impact due to environmental elements such as rain, hail, wind-driven debris, and the like. The back or bottom layer is an electrical contact that often covers the entire back or bottom surface of the cell structure. A thick metal electrical contact on the bottom surface, or below, for example, the n-type material shown in FIG. 1, is also provided in a typical solar cell. Positive and negative terminals may also be provided for electrical connection to the solar cell.

Photons in sunlight that hit the solar cell may be absorbed by the semiconducting materials. As sunlight is absorbed into the semiconductor material, electrons are knocked from their respective atoms by photons and permitted to flow through the semiconductor material. In particular, in a solar cell electron-hole pairs and/or positive and negative charges are generated, and separated within and/or near the p-n junction or depletion region, thereby building up a charge that also generates a voltage and current in the solar cell. The electrical charges are then collected by the electrical contacts and transferred through terminals connected to the semiconductor material.

To decrease the cost of solar energy generally, high-efficiency solar cells are desired. The overall efficiency of a solar cell is the product of the reflectance efficiency, the conversion or quantum efficiency, the charge carrier separation efficiency, and the conductive efficiency. There are many contributors to the cell's inefficiency, including for example: (1) the top metal contact or material provided on the top or sun facing surface is not optically clear and may reflect or absorb incoming photons; (2) the junction's depletion region or space charge region is finite and distant from the cells front and back surface and, as such, it will only convert a fraction of the incoming photons to electrons; (3) photons with energies less than the bandgap voltage of silicon will be absorbed; and (4) the recombination of electron-hole pairs as the electrons transit the material to the contacts. Existing photovoltaic (PV) cells have limited efficiency due to the structure employed. The layers of a typical PV cell are shown in FIG. 1. Because the semiconductor material has a finite thickness from the top surface to the junction, only photons of certain energy levels will spawn electron-hole pairs in the vicinity of the junction or depletion region to generate usable current. For example, if the junction is 2 microns deep into the p-type semiconductor and that junction has a depletion layer depth of 0.8 microns (±0.4μ), then the fraction of violet photons captured in the junction will be approximately 0.16 or 16%. For infrared photons the fraction will be approximately 0.14 or 14%. The maximum efficiency of a single lateral p-n junction silicon cell is set by the Shockley-Queisser limit of 33.7% [1].

The absorption of photons is set by a quantum effect that was first described by Einstein [2]. Absorption occurs when the photon's energy, in electron volts, is less than the photo-electric work function of the material [2]. This means that a photon must have energy at least equal to the work function of the material in order to spawn (i.e., free) an electron-hole pair. The work function of some example materials is noted in the table below.

TABLE 1

| Material | Photo-electric Work Function (eV) |
|---|---|
| Aluminum | 4.06-4.26 |
| Silicon | 4.60-4.85 |

The energy of a photon relates to its frequency times Planck's constant. The energy of a photon also relates to its frequency and wavelength. More specifically, high frequency (short wavelength) photons carry more energy than low frequency (long wavelength) photons. Example energies for some colors of light (photons) are shown in the table below.

TABLE 2

| Color | Near IR | Red | Blue | Deep Violet |
|---|---|---|---|---|
| Wavelength (nM) | 1200 | 650 | 475 | 400 |
| Frequency (Hz) | 2.5E14 | 4.62E14 | 6.32E14 | 7.5E14 |
| Energy (eV) | 1.035 | 1.913 | 2.616 | 3.105 |

A simple model of the actual energy generated by the sun, at any wavelength, can be seen by evaluation of the following equation using the blackbody temperature of 5250 degrees Kelvin.

$${I}^{′} ( λ , T ) = \frac{2 {hc}^{2}}{{λ}^{5}} \frac{1}{{e}^{\frac{hc}{λ kT}} - 1} . \qquad [ 1 ]$$

Where h is Planck's constant, c is the speed of light, e is the natural logarithm base, and k is the Boltzmann constant.

Evaluation of the foregoing Equation 1 yields the graph shown in FIG. 2 of radiation per square-meter that reaches the earth. Integrating the received radiation in the optical window, between 400 and 1200 nanometers (nm), yields the available energy. The result is a power density of about 800 watts per square-meter in the 800 nm range.

The energy of photons that penetrate the optical window (400 to 1200 nm) of the atmosphere is too small to generate free electron-hole pairs in pure silicon. However, this is not the case when a semiconductor junction (depletion region) is present. The effective work function in the vicinity of the depletion region of a junction is reduced from that of pure silicon to the bandgap energy of silicon, or about 1.2 electron volts (eV). Thus, any infrared photons falling on the cell will only act to generate heat since their energy is lower than the bandgap energy. Taking this into account, the power density is reduced to about 600 watts per square-meter at sea level.

Referring again to FIG. 1, absorption will occur since the p-type material has a finite thickness from the surface to the depletion layer (near the junction). Moreover, other photons may pass through the junction and be adsorbed in the n-type material. The holes must also travel through the n-type material to reach the lower contact. In the process many holes are annihilated because of the distance traveled. The absorption process involves the generation of electron-hole pairs that are self-annihilated.

The efficiency of the solar cell is further limited by the top contacts which may interfere (e.g., by reflection, adsorption, etc.) with incoming photons that would otherwise reach the junction or depletion region at a certain energy level.

In an attempt to increase the cell efficiency, some traditional cells utilize a stack of lateral or horizontally arranged junctions. However, such an arrangement of lateral junctions suffers from the same drawbacks discussed above.

### SUMMARY

Accordingly, a solar cell is provided. The solar cell includes a p-type doped semiconductor material and an n-type doped semiconductor material laterally adjacent to the p-type material. The materials form a stripped structure with finite depth. The p-type material and n-type material form a vertically structured diode at the junction of the p-type material and n-type material, wherein the vertically structured diode has its depth determined by a multiple of the electromagnetic properties, and in particular skin depth, and the width of the depletion layer is controlled by the doping concentrations of the p-type and n-type material.

A further embodiment of a solar cell is also disclosed. The solar cell includes a first region formed of a p-type semiconductor material and a second region formed of an n-type semiconductor material. A vertically structured photodiode is provided between the first region and second region having a depth determined by a multiple of an electromagnetic skin depth of at least one of the p-type material or n-type material and width of a depletion region controlled by a doping concentration of the p-type and n-type material. A refractory material is also provided forming an optical element on a sun facing surface of the solar cell adapted to direct photons to a depletion region of the vertically structured photodiode.

### BRIEF DESCRIPTION OF THE DRAWINGS

Various examples of embodiments of the systems, devices, and methods according to the present disclosure will be described in detail, with reference to the following figures, wherein:

FIG. 1 is an example of a prior art solar cell shown in cross-section;

FIG. 2 is a graph of the solar radiation spectrum showing the relation of spectral irradiance to wavelength.

FIG. 3 is an isometric view of one or more examples of embodiments of the solar cell showing an array of light collecting structures on the sun facing side of the solar cell.

FIG. 4 is a cross-section view of one or more examples of embodiments of the solar cell array shown in FIG. 3, taken from line 4-4 of FIG. 3;

FIG. 5 is an alternative example of one or more embodiments of the solar cell array shown in FIG. 3, showing a cross-section view of a simplified solar cell array;

FIG. 6 is a cross-section view of a solar cell for use in the solar cell array shown in FIG. 3, according to one or more examples of embodiments.

FIG. 7 is an isometric view of a solar cell structure according to one or more examples of embodiments.

FIG. 8 is a cross-sectional view of the solar cell structure shown in FIG. 7, taken from line A-A of FIG. 7, showing a non-isolated solar cell structure in one or more examples of embodiments.

FIG. 9 is a cross-sectional view of the solar cell structure shown in FIG. 7, taken from line A-A of FIG. 7, showing an isolated solar cell structure in one or more alternative examples of embodiments.

FIG. 10 is a graph of the transmission of photons for n-type and p-type semiconductor material with regard to violet radiation and infrared radiation, showing the fraction of photons available in relation to the depth of semiconductor material.

FIG. 11 is a graph of the fraction of production of electrons from violet light as a function of distance into the depletion layer for n-type and p-type semiconductor material, showing the fraction of production of electrons from violet light in relation to the depth of semiconductor material.

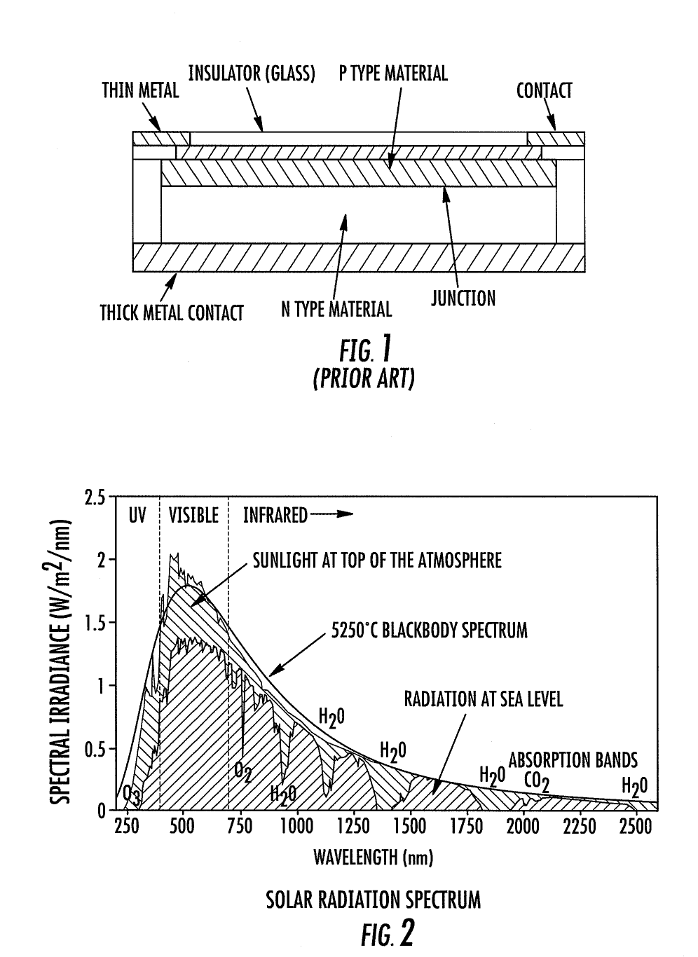

It should be understood that the Figures are not necessarily to scale. In certain instances, details that are not necessary to the understanding of the invention or render other details difficult to perceive may have been omitted. It should be understood, of course, that the invention is not necessarily limited to the particular embodiments illustrated herein.

### DETAILED DESCRIPTION

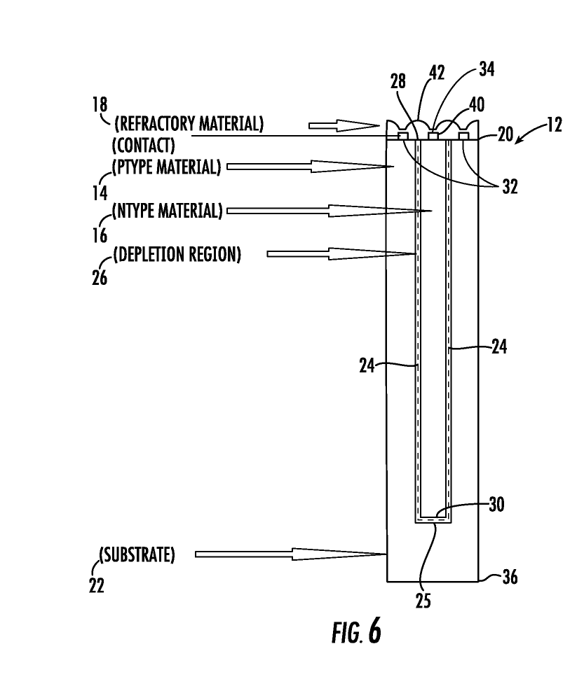

FIGS. 3-6 show, generally, a section or segment of a solar or photovoltaic cell array 10 in accordance with one or more examples of embodiments. The solar cell array 10 includes a plurality of solar cells 12. Each solar or photovoltaic cell 12 includes semiconductor material 14 and/or 16 which forms the cell, as well as one or more optical elements 18 or material interposed between the incident light source and the light receiving surface 20 of the semiconductor material.

The solar cell 12 of one or more examples of embodiments, shown in FIGS. 3-9, includes semiconductor material and/or a plurality of such materials 14, 16. The semiconductor material described herein for purposes of discussion and illustration includes p-type semiconductor material 14 or silicon and n-type semiconductor material 16 or silicon. However, existing and future developed materials having similar properties may be acceptable for purposes of the present invention.

Materials suitable for the solar cells 12 described herein may be matched to the spectrum of available light and may be arranged in multiple physical configurations suitable for the purposes provided herein. Examples of suitable materials for use in one or more examples of a solar cell 12 described herein include mono-crystalline silicon, amorphous silicon, cadmium telluride, and copper indium selenide/sulfide, and/or other now known or future developed silicon forms, as well as combinations of the foregoing. The semiconductor material may be comprised of any semiconductor material such as carbon, germanium, tin, or lead, or combinations thereof, but it is preferably comprised of silicon. The p-type conductivity semiconductor material 14 may be formed by doping the semiconductor material with a p-type dopant, such as, but not limited to boron. The n-type conductivity semiconductor material 16 may be formed by doping the material with an n-type dopant, such as, but not limited to phosphorous, arsenic, or antimony, or combinations thereof.

The semiconductor material 14, 16 may be formed by any now known or future developed means. In one or more examples of embodiments, the solar cell 12 may be made from bulk materials that are cut into wafers, ingots, or ribbons, and processed. It is also contemplated that the material may be made of a thin film or layer, organic dye, and/or organic polymer that is deposited on a supporting substrate 22. The cut silicon material may then be doped by the addition of the doping materials described hereinabove by now known or future developed means. It is contemplated that one or more antireflection coatings may be applied, although such coating is not required. For example, the upper or light receiving surface 20 of the solar cell array 10 may be coated with an antireflective coating (not shown).

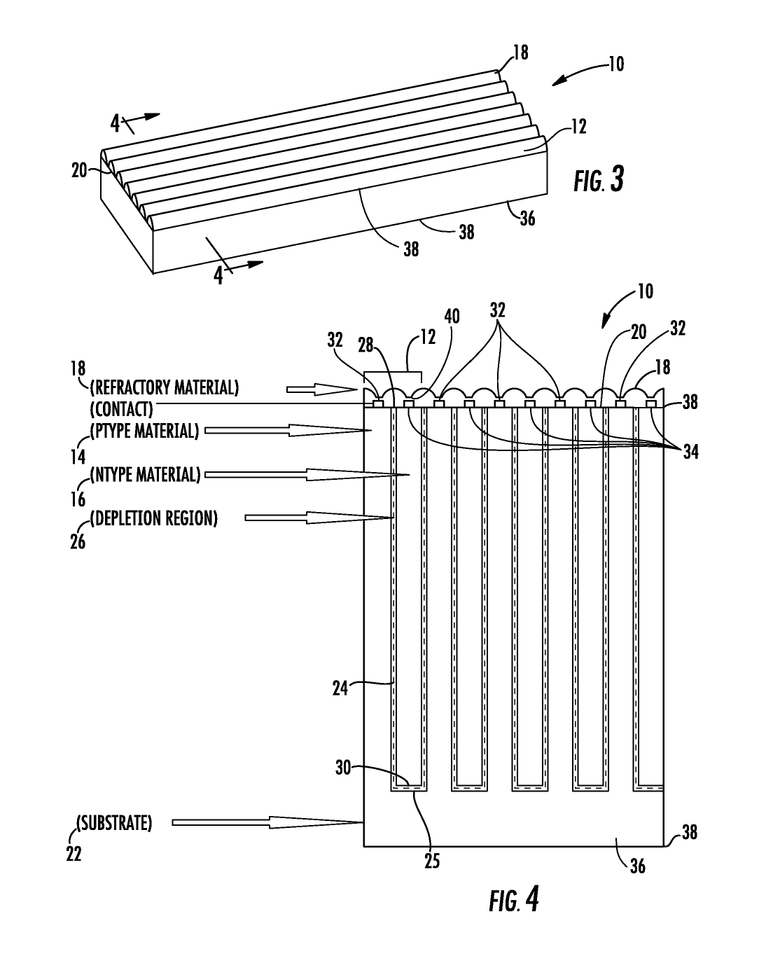

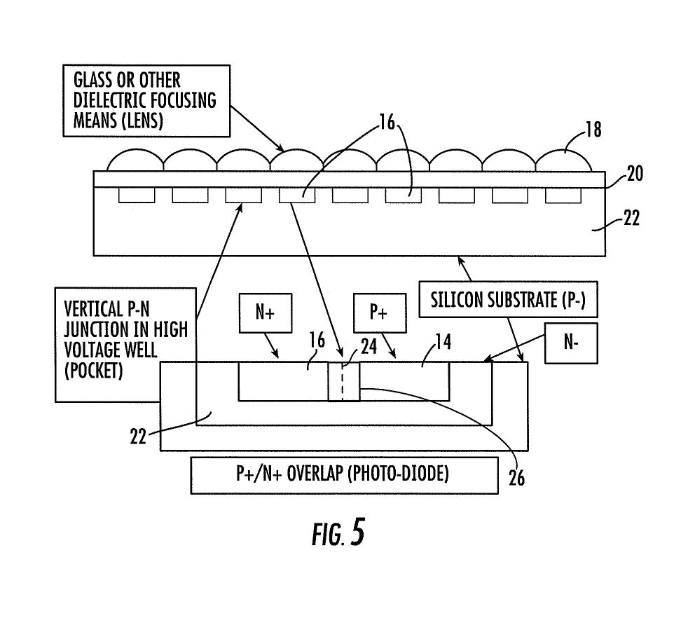

In one or more examples of embodiments of the solar cell 12, as shown in FIGS. 3-9, the p-type material 14 is positioned laterally adjacent to the n-type material 16. Further, the light receiving or facing surface 20 of the solar cell 12 is formed at the top surface of the laterally adjacent p-type material 14 and n-type material 16 regions, or is co-planar with a segment of both the p-type material 14 and the n-type material 16 regions. A p-n junction 24 and/or depletion region 26 is created by or at the overlap of a p or p(+) type conductivity region and an n or n(−) conductivity region (e.g., similar to a junction of a Zener diode) which gives rise to a photovoltaic effect, forming a photodiode. The p-type conductivity and n-type conductivity material form the vertical p-n junction 24 between the p-type and n or n-type conductivity material as shown, for instance, in FIGS. 3 and 4. Thus, in the arrangement shown in FIGS. 3-6, the semiconductor material 14, 16 includes one or more substantially vertical structure diodes, or vertically structured diodes, each having a vertical or substantially vertical p-n junction 24 and/or depletion region 26 (i.e. a p-n junction 24 or depletion region 26 oriented substantially perpendicular to the light receiving surface 20 of the semiconductor material 14, 16, and/or a p-n junction 24 or depletion region 26 oriented substantially parallel to the incident light under certain conditions). In this orientation, a segment 28 of the junction 24 and depletion region 26 may also be co-planar with the top surface or sun facing surface 20 of the cell 12. In various examples of embodiments, and while not shown in the cross-sectional views in FIGS. 4-6, the junctions 24 and/or depletion regions 26 extend laterally and are relatively long compared to their width.

In various embodiments, and as shown in FIGS. 3-9, a substrate 22 is provided below and/or surrounding or substantially surrounding the p and/or n-type conductivity material 14, 16. The substrate 22 may be provided which is fabricated of a semiconductor material, which may be but is not necessarily, silicon and may or may not be a doped silicon. The substrate 22 may be of a p-type or an n-type conductivity, or be formed of any suitable alternative material for charge transmission and/or support of the solar cell 12. For instance, the substrate 22 material may also be glass or carbon or one or more of silicon, glass, or other materials or a combination of such materials. In one or more examples of embodiments, the substrate 22 is formed of a p-type material 14. In a solar cell module or an array of solar cells 10, as shown in FIG. 4, the p-type material region 14 may be positioned laterally adjacent each n-type material region 16 and further surround the lower edge 30 of the n-type material portion 16 forming a lower p-type substrate 22 portion. In this regard, a p-type material block having n-type pockets of material therein may be provided. In this arrangement in which the p-type material region 14 substantially surrounds the n-type material 16 on approximately three sides (forming a junction therebetween), a small horizontally positioned or arranged p-n junction 25 may be present at the intersection of the p-type material 14 and n-type material 16 at the lower edge 30. Thus, the cell's structure may include an n-type pocket or a plurality of n-type pockets within a p-type material 14, allowing sections of the cell 12 to be placed in a series configuration, providing higher cell voltage while keeping the current in the contacts small.

FIGS. 7-9 illustrate one or more examples of a solar cell 12 structure. As shown in FIG. 7, the solar cell 12 structure may be formed of a block of a first material, such as a p-type material 14, containing one or more bars or segments of a second material, such as an n-type material. As can be seen in FIGS. 7-9, the bars of material 16 may have a narrow width, extend from a sun facing surface 20 to a predetermined depth into the first material 14, and extend longitudinally along an axis or plane of the block of first material 14. In FIGS. 7-9, the first material 14 surrounds or substantially surrounds the bar of second material 16 on the side surfaces, end surfaces, and lower surfaces, each of which extend or are positioned below the sun facing surface 20 of the cell 12, however variations thereon may be made without departing from the overall scope of the present invention. Charges 27 may diffuse or transit through the material to collection means on one or more surfaces of the block.

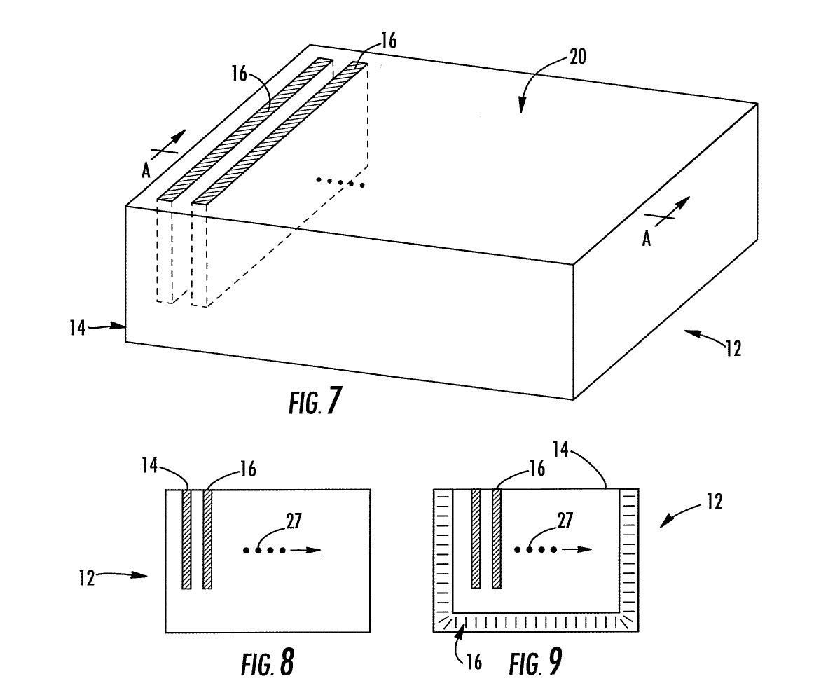

As can be further seen by a comparison of FIGS. 8 and 9, the solar cell 12 structure may be formed as an isolated solar cell (FIG. 9) or non-isolated solar cell (FIG. 8). In the isolated solar cell, the second material 16, which also forms the bars of material, may be provided along the outer edges of the block and spaced from the bars. As shown in FIG. 9, the second material 16 is provided on the sidewalls and lower wall or bottom of the block.

While FIGS. 7-9 and the description herein identifies p-type material 14 as the first material and n-type material 16 as the second material, these material types or forms may be interchanged. Alternative materials and types may also be acceptable for purposes of the present invention.

In various embodiments, electrical contacts or electrodes 32, 34 are electrically coupled to each of the p-type and n-type conductivity material 14, 16, 22 forming the junction 24 or depletion region 26. In various embodiments, and as shown in FIG. 5, electrical contacts or electrodes 32, 34 are provided or formed, respectively, to each side of the junction 24 or depletion region 26.

Electrical contacts 32, 34 are provided for energy collection and generation. In the illustrated example, a plurality of electrical contacts 32 are provided on the top surface 20 of the solar cell 12 or solar cell array 10. The plurality of electrical contacts 32 are spaced apart across the top surface 20 and may be interconnected to form a single device. In FIG. 4, the electrical contacts 32 are illustrated to be positioned between adjacent solar cell junctions 24 on the top surface 20. In an alternative example of embodiments, an electrical contacts 32 in the form of a grid having a plurality of open areas may be provided on the top surface 20. An additional electrical contact 34, which may be a thick or a thin electrical contact, is provided on the lower or bottom or back surface 36. Electrical contact 34 may cover the entire solar cell surface 36 or array surface, or may cover portions thereof. One or more electrical terminals (not shown) for the transmission of current to and from the cell 12 may also be provided in electrical contact or communication with the upper and lower contacts 32, 34 of the cell 12.

Each electrical contact 32, 34 includes, or is formed of, conductive material for collection and/or transmission of electrical current. The electrical contact or electrodes may be made of any conductive material. For example, the contact or electrodes may be constructed of aluminum or an aluminum alloy. The electrical contacts 32, 34 are formed in accordance with methods known to or hereafter developed by those skilled in the art of solar cells.

The electrical contacts or metal electrical contacts include sidewalls 38 (see FIGS. 3-4). These sidewalls and/or the electrical contact may be formed of, or include a material which acts as a reflective surface that will direct low angle of incidence photons toward the sensitive area or junction of the solar cell 12.

The front or top electrical contact or plurality of electrical contacts 32, and the back or bottom electrical contact 34 may be attached to the solar cell 12 or the solar cell array 10. In one or more examples of embodiments, the electrical contact may be separately formed and adhered to the semiconductor material 14, 16. After the electrical contacts are made, terminals may optionally be provided. The solar cells 12 may be interconnected in series and/or parallel, by for example, flat wires or metal ribbons and assembled into modules or arrays or solar panels. The modules or arrays may be connected or interconnected in series or parallel as well.

Multiple cells 12 may be coupled in series or in parallel (of some combination thereof) depending upon a variety of considerations. A plurality of solar cells 12 may be connected in series, for example in one or more modules, to create an additive voltage. Likewise, solar cells 12 may be connected in parallel to produce a higher current. The array preferably has a desired peak voltage and current. In various examples of embodiments, the cells 12 are coupled in series so that the current is substantially constant even as voltage increases.

The efficiency of the solar cell 12 according to one or more examples of embodiments may be achieved and controlled by keeping relative dimensions of the components of the solar cell small in size.

In operation of a solar cell 12 or solar cell array 10 according to one or more examples of embodiments, generally, a photon, as an electromagnetic entity, will penetrate the semiconductor material 14 and/or 16 to a probabilistic depth based upon the electro-magnetic skin depth of the material (i.e., the semiconductor material) and the frequency (f) of the photon. The skin depth (δ) is a function of the material and described in the following formula:

δ=50.33E6(ρ/μ*f)^{1/2} (micrometers) [2]

where ρ is the resistivity (ohm-cm) of the material and μ is the magnetic permeability relative to air. This yields the following typical skin depths (micro-meter):

TABLE 3

| | Glass | Aluminum | P-type Si | N-type Si |
|---|---|---|---|---|
| Infrared | 1.001E7 | 5.345E−4 | 3.339 | 2.847 |
| Ultraviolet | 5.812E6 | 3.086E−4 | 1.927 | 1.344 |

It is noted that the actual resistivity of doped silicon is a function of the doping concentration. For purposes of illustration, a doping concentration of 1E16 is used in the table above.

The wavelength of light (photons) that can penetrate the atmosphere which surrounds the earth (i.e., the atmospheric window) is in the range of 400 nanometers to 1,200 nanometers. The corresponding frequency is then given by c/λ, where c is the speed of light such that the frequency of near ultraviolet light is 7.5E14 cycles per second and infrared light is 2.5E14 cycles per second.

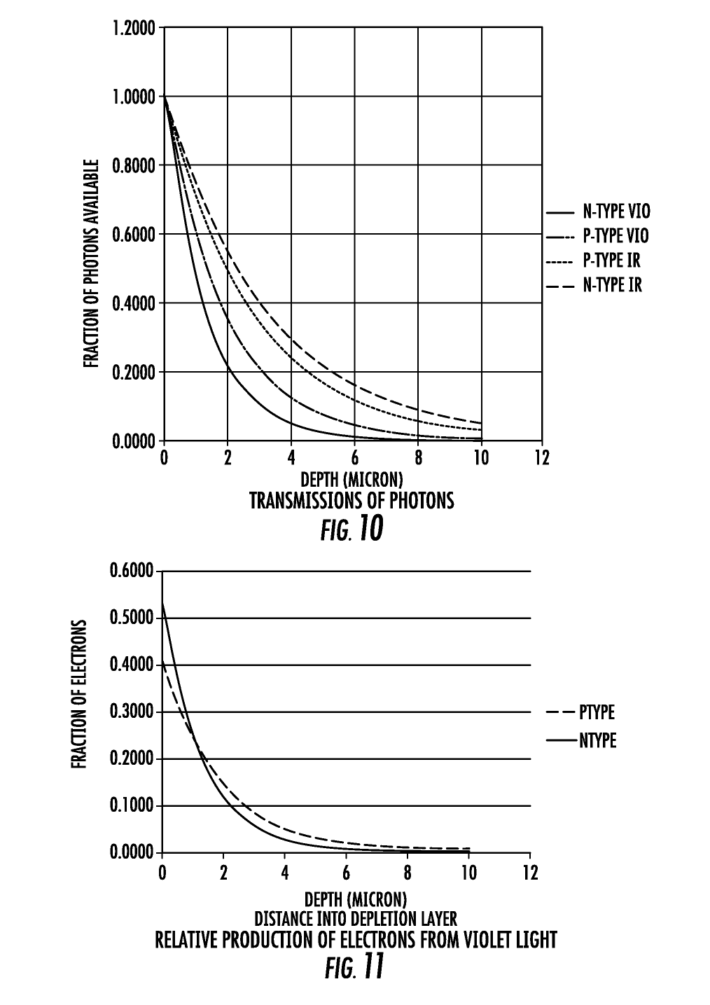

Solving Equation 2 for the photons available at the depth into the material at various frequencies with a known doping concentration yields the results shown in FIG. 10. The photons that spawn electron-hole pairs in the vicinity of the junction's depletion layer will generate most of the useable electrical current because the work function inside the depletion layer is significantly smaller than that of the nearby silicon. From the data shown in FIG. 10 it can be appreciated that by having a depletion layer 26 of a finite thickness centered at a known depth, the fraction of photons captured in the layer sets the efficiency of the conversion of photons to electrons, provided the photons have energies equal to or greater than the junction's bandgap energy (i.e., the energy required to free an outer shell electron from its orbit about the nucleus to become a mobile charge carrier, able to move freely within the solid material—generally, the band gap determines what portion of the solar spectrum a photovoltaic cell absorbs).

Maximizing the conversion of photons into free electrons and holes, and then into useable current, or a change in electronic charge in time, is the goal for a high efficiency cell 12. The end result of free electrons per photon sets the maximal efficiency of a PV cell 12. As can be determined by reference to FIG. 10, most photons will generate electrons near the surface 20 of the cell 12. The electrons generated near the surface 20 of the cell 12 will travel only short distances in the semiconductor material 14 and/or 16 before they exit the cell 12. On the other hand, electrons that are generated near the bottom of the cell 12 must travel longer distances and will face greater possibilities of recombination. Thus, the key constraining elements are the depth in a material in which electron-hole pair generation occurs and the lifetime of the electron-hole pair as it relates to recombination or annihilation of the electron-hole pair.

The generation of electron-hole pairs is governed by the electromagnetic properties of the materials bombarded by the photons. The frequency of the photon, the magnetic permeability, and the resistivity of the cell's materials control the effect. The relationship may be modeled by the following:

$$\frac{current at depth Z}{current at surface} = {e}^{- Z / δ} \qquad [ 3 ]$$

Where: δ is the skin depth of the material in microns.

δ(microns)=50.33*10⁶2\sqrt{ρ/μf} [4]

Where: ρ is the volume resistivity of the material, μ is the relative permeability, and f is the frequency in cycles per second (Hertz [Hz]). The resistivity ρ (ohm-cm) can be found using the following:

$$ρ = \frac{1}{N * Qe * μ} \qquad [ 5 ]$$

Where: N is number of doping particles per cm³, Qe is the charge of an electron, and μ is the mobility.

As indicated, the wavelength range of light that penetrates the earth's atmosphere ranges from approximately 400 nanometers (deep violet) to 1200 nanometers (near infrared). The relationship of wavelength to frequency is given by:

f=c/λ [6]

Where: c is the speed of light (3*10⁸ M/s) and λ is the wavelength (M). Performing the conversion using Equation 6 for light which reaches the earth's atmosphere yields 250 terahertz for near infrared wavelength of light to 750 terahertz for deep violet wavelength of light in the frequency domain.

In one or more examples of embodiments, the vertically structured diode 24, 26 has dimensions controlled by the impurity doping concentration and/or a multiple of the semiconductor material's 14 and/or 16 skin depth. The skin depth may also be controlled by doping. The silicon semiconductor material 14 and/or 16 described herein has bulk or volume resistivity that is a function of the impurity doping concentration. For example, a doping concentration of 10¹⁵ is typical for a semiconductor having low bulk resistivity or high conductivity. The greater the doping level, the thinner the depletion layer 26 width or thickness, such that there is a tradeoff between conductivity and depletion layer 26 width. In one or more examples of embodiments, it is desirable to have low resistivity material in order to minimize resistive losses as the generated photocurrent is removed from the device. However, actual doping levels and relative doping levels may vary to maximize efficiency, or as desired, or based on other considerations such as ease of manufacture, cost, and the like.

According to one or more examples of embodiments, the depletion layer 26 is wide enough to capture the incoming photon. The depletion layer 26 width (thickness) is given by:

$$W = {[ \frac{2 {K}_{s ε 0}}{q} ( \frac{{N}_{A} + {N}_{D}}{{N}_{A} {N}_{D}} ) ( {V}_{bi} - V ) ]}^{\frac{1}{2}} \qquad [ 7 ]$$

Where: Kₛ is the semiconductor dielectric, q is the charge of an electron (−1.602×10⁻¹⁹ coulombs), ∈o=8.854×10⁻¹² F/m is a constant, N_{A} and N_{D} are the respective doping levels, V_{bi} is the built-in voltage, and V is the applied bias. The width (W) may vary by approximately 1/Nx if all other factors remain constant. Accordingly, as indicated above, and can be seen by Equation 7, the width of the depletion layer 26 becomes smaller as the doping level of the semiconductor material 14 and/or 16 increases. Thus, the doping level may control the width of the depletion layer 26. For example, in a solar cell 12 with no voltage applied across the device and a doping level as shown above, the width of the depletion layer 26 is approximately 0.6 microns (micrometers). Preferably, in one or more examples of embodiments the width of the depletion layer 26 is at least one quarter (¼) of the longest wavelength of incoming light expected, and more preferably approximately 300 nanometers. Further, the width of the depletion layer may be controlled by the voltage that appears across the solar cell. For example, the depletion layer width decreases as the voltage increases.

In addition, the vertical junction 24 or depletion region 26 dimensions may be influenced by the skin depth of the material. The skin depth, in one or more examples of embodiments, relates to the distance from the surface, perpendicular to the surface, to the point of interest. The efficiency of the solar cell 12 having a vertically structured diode 24, 26 as described herein is maximized by keeping the path length of the generated electrons very small, while maintaining the junction 24 depth large enough to assure the conversion of the photons into electron-hole pairs.

In one or more examples of embodiments, a solar cell 12 using p-type (10¹⁶ molecules per cm³) and n-type (3.4*10¹⁵ molecules per cm³) semiconductor materials 14, 16 is provided and has the following characteristics:

TABLE 4

| | RESISITIVITY | PERMAEBILITY | MOBILITY |
|---|---|---|---|
| MATERIAL | (ohm-cm) | (μᵣ) | (cm²/V-s) |
| N-type Silicon | 1.42 ohm-cm | 1.00 | 1290 |
| P-type Silicon | 1.45 ohm-cm | 1.00 | 429 |

Using these physical values the skin depths, according to Equation 4, are:

TABLE 5

| Material | F = 250 THz | F = 750 THz |
|---|---|---|
| N-type | 3.79 microns | 2.18 microns |
| P-type | 3.83 microns | 2.21 microns |

One skin depth is the depth where 63% of the photons will have generated electron-hole pairs.

The diode or vertical junction 24, in one or more examples of embodiments, has a depth of at least 3 skin depths of p-type silicon material 14, and more preferably, approximately 10 micrometers (μM). At three skin depths approximately 95% of the photons will have generated electron-hole pairs. In particular, approximately 95% of lower frequency photons (e.g., 2.5E14 cycles per second (Table 2)) will be converted to electron-hole pairs in a junction 24 height of 3 skin depths, and approximately 99% of photons will be converted to electron-hole pairs for higher frequency light (e.g., 7.5E14 cycles per second (Table 2)) at the same junction height or depth.

As electron-hole pairs are generated in the depletion layer 26 they are separated by the built-in electric field. The build-in electrical field is naturally occurring when a depletion region is formed. The velocity of the electrons is given by the following formula:

Ve=mobility*E=1290*2300=2.967*10⁶ cm/s [8]

The built-in potential of about 0.5 volts yields an electric field of approximately 2.3 thousand volts per centimeter. Applying this value to Equation 8, the built-in electric field has the effect of moving the electrons through the depletion layer 26 in about 200 picoseconds. By comparison, the holes of the electron-hole pairs move in a direction opposite to the electrons and transit the depletion layer 26 in about 600 picoseconds. As a result of the velocity at which the charges move through the depletion layer 26, little recombination occurs.

However, the charges still must propagate from the depletion layer 26 boundary, which may include doped silicon, to the electrical contacts 32, 34. The transit time will vary with the distance involved for each individual charge. Since most photons are converted near the top or outer edge of the junction 24 (FIG. 10) many charges will have a small distance to travel. The distance the electrons have to travel to exit the cell 12 is very small for 40% to 50% of the electrons, but as the distance increases the percentage of electrons also decreases. For example, this can be seen by observing the relative production of electrons from violet light as a function of distance into the depletion layer 26 (FIG. 11).

During the time it takes to transit the distance from the depletion layer 26 boundary to the electrical contacts 32, 34, some charges may also encounter other species and recombine. This effect is known as the probability of recombination and is modeled by the following formulas. Electron lifetime (seconds) is estimated by:

$${τ}_{e} ≅ \frac{1}{( 3.45 * {10}^{- 12} * N ) + ( 9.5 * {10}^{- 32} * {N}^{2} )} \qquad [ 9 ]$$

Where: N is the acceptor doping density. For materials with doping densities in the range of those described herein, the second term (K*N²) in the denominator is small and can be ignored.

The lifetimes for holes can be estimated by:

$$τ ≅ \frac{1}{( 7.8 * {10}^{- 13} * {N}_{d} )} \qquad [ 10 ]$$

The electron diffusion length (cm) in p-type material 14 is approximated by the following equation:

$${L}_{e} = \sqrt{\{ ( \frac{kT}{q} ) * {μ}_{e} * {τ}_{e} \}} \qquad [ 11 ]$$

Where: k is the Boltzmann constant, T is the absolute temperature (K), q is the charge, uₑ is the electron mobility, and τₑ is the electron lifetime. At room temperature the value of KT/q (thermal voltage) is 0.0252 volts. The electron diffusion length is the distance in the material where the probability of recombination is unity.

Using Equations 9, 10, and 11, the carrier lifetimes and diffusion lengths for the n-type and p-type semiconductor materials 14, 16 described herein are as follows:

TABLE 6

| | | |
|---|---|---|
| Material | Minority Carrier Lifetime | Diffusion Length |

| | | | |
|---|---|---|---|
| N-type (donor) | 376 | uS (hole) | 177 u |
| P-type (acceptor) | 29 | uS (electron) | 1100 u |

Solving for the probability of an electron and a hole reaching their respective electrical contacts 32, 34 yields the final probability of a generated electron reaching the contact of:

Pₑ=1−(D/1100u) [12]

and yields a final probability of a generated hole reaching the contact of:

Pₕ=1−(D/177u) [13]

where D is the distance traveled to exit the cell 12. Considering that both an electron and hole must reach their respective contacts for current to flow, it is assumed that the worst case probability dominates.

As electrons are generated at a rate that is a function of the depth into the depletion region 26 and that same depth sets the path length for the charge to exit the cell 12, the effect on total efficiency is determined by multiplying the functions. The result for the solar cell 12 described herein is a conversion rate (transit) of approximately 99%. However, accounting for inefficiencies due to infrared heating (quantum efficiency) yields a cell 12 with an overall conversion efficiency of about 74%. That is:

(Quantum efficiency=0.75(600/800))*(Transit efficiency=0.99)=(Total conversion efficiency(“TCE”)=0.74). [14]

Total overall efficiency=TCE*optical efficiency(0.9)=0.67

To retain the overall conversion efficiency at the level of 74% or to increase the efficiency, in one or more examples of embodiments, a means is provided to guide photons which contact the solar cell 12 or solar cell array 10 to the region of the depletion layer 26. For example, if 90% of the photons of the incident light or radiant energy absorbed by each solar cell 12 can be directed to the junction 24 and/or depletion region 26, then the efficiency of the solar photovoltaic cell 12 may be in excess of 80%. This is accomplished by a focusing means or optical element 18 or material positioned on the top or sun facing surface 20 or side of the semiconductor material 14, 16. In one or more examples of embodiments, the focusing means or optical element 18 or material includes, but is not limited to, a lens. The optical element 18 is adapted to change the direction and/or focus at least some of the radiant energy that reaches the solar cell 12 so as to direct photons to the depletion layer 26. The optical element 18 or material is adapted to gather, focus, direct, re-direct and/or otherwise change the direction of at least some of the incident light or radiant energy toward one or more p-n junctions 24 and/or depletion regions 26 in the semiconductor material 14, 16 or solar cell 12 or solar cell array 10.

The optical element may be formed of any suitable shape or arrangement. In the examples illustrated in FIGS. 3-6, a lens is provided having an arcuate shape or cross section, such as for example, a curve, a semi-circle, an arc, or a portion thereof. However, any shape suitable for focusing incident light on the sensitive area or desired region of the photodiode may be acceptable for the purposes provided. The lens or optical element 18, as shown in FIGS. 3-6, has an arcuate portion which is outwardly curved, such that the apex 42 of the lens extends away from the semiconductor material 14, 16.

Each optical element 18 or lens may be seated, as shown in FIG. 4, such that the apex 42 of the curve is positioned approximately above the depletion region 26 and/or junction 24. The shape of the curve is further arranged such that the incident light is focused toward the sensitive area of the solar cell 12, and in particular the vertical diode including the depletion region 26 and junction 24 below the apex 42 of the optical element 18.

The optical element 18 or material may be made of any suitable refractory material or any other dielectric material. Examples of suitable materials include, but are not limited to, glass or SiO₂ and polymers, such as acrylic, as well as combinations of the foregoing. In one or more examples of embodiments, the optical element 18 or material or lens is small in size. For example, the optical element may have a radius of curvature ranging from one (1) micrometer to two (2) micrometers.

In various embodiments, the optical element 18 or material is provided on the semiconductor material 14, 16. In various embodiments, the optical element 18 or material is formed directly on a semiconductor (e.g. Silicon) wafer. In one or more alternative examples of embodiments, and as shown in FIG. 4, the optical element 18 may be formed on, carried by, or seated on one or more electrical contacts 32 carried by the top surface 20 of the solar cell 12 or solar cell array 10. As illustrated in FIG. 4, the contact surface 40 of each individual lens or lens segment may be seated on the electrical contact 32, such that a majority of the focusing area of the lens is unimpeded by the electrical contact. The optical element 18 or material may be formed of a single sheet of material shaped to form one or more optical elements, focusing elements or lenses, or may be a plurality of segments having one or more such devices. While the optical element 18 or material is shown in the Figures as a series of lenses or optical elements having an arcuate shape, the optical element or material or lens may comprise any variety of shapes, arrangements, and cross-sectional shapes.

According to the foregoing embodiments, a solar cell 12 is provided which includes a p-type doped semiconductor material 14 and an n-type doped semiconductor material 16 laterally adjacent to the p-type material. The p-type material 14 and n-type material 16 form a stripped structure with a finite depth. The p-type material 14 and the n-type material 16 also form a vertically structured diode at the junction 24 of the p-type material and n-type material. The vertically structured diode has its depth determined by a multiple of an electromagnetic skin depth of either or both the p-type material or n-type material. The vertically structured diode also includes a depletion layer 26 having a width which is controlled by a doping concentration of the p-type and n-type material 14, 16. In one or more examples of embodiments, a refractory material may also be provided which forms an optical element on a sun facing surface 20 of the solar cell 12 adapted to direct photons to the depletion region 26 of the vertically structured photodiode.

Solar cells having one or more p-n vertical junctions forming a photodiode and/or a light sensitive area formed by an array of optical elements capable of changing the direction of incoming radiation to help direct it toward the junctions are described herein. The efficiency of the solar cell is enhanced over existing solar cells by using a vertical depletion layer (junction) structure. The vertical structure has no electrode on top of the photodiode (junction) and therefore no intensity reducing properties. In addition, the arrangement provides a large vertical surface area for the junction/depletion layer structure, resulting in improved efficiency over existing devices. For instance, the depletion layer surface area is approximately four times that of a conventional lateral cell. Four times the surface area increases the probability of converting photons to electrons. Moreover, the benefit of a vertical structure is maximized by keeping the path length of the generated electrons very small while keeping the junction depth large enough to assure the conversion of the photons. These and other advantages will be apparent from the foregoing description and following claims.

As utilized herein, the terms “approximately,” “about,” “substantially”, and similar terms are intended to have a broad meaning in harmony with the common and accepted usage by those of ordinary skill in the art to which the subject matter of this disclosure pertains. It should be understood by those of skill in the art who review this disclosure that these terms are intended to allow a description of certain features described and claimed without restricting the scope of these features to the precise numerical ranges provided. Accordingly, these terms should be interpreted as indicating that insubstantial or inconsequential modifications or alterations of the subject matter described and claimed are considered to be within the scope of the invention as recited in the appended claims.

It should be noted that references to relative positions (e.g., “top” and “bottom”) in this description are merely used to identify various elements as are oriented in the Figures. It should be recognized that the orientation of particular components may vary greatly depending on the application in which they are used.

For the purpose of this disclosure, the term “coupled” means the joining of two members directly or indirectly to one another. Such joining may be stationary in nature or moveable in nature. Such joining may be achieved with the two members or the two members and any additional intermediate members being integrally formed as a single unitary body with one another or with the two members or the two members and any additional intermediate members being attached to one another. Such joining may be permanent in nature or may be removable or releasable in nature.

It is also important to note that the construction and arrangement of the elements of the solar cell as shown in the preferred and other exemplary embodiments is illustrative only. Although only a few embodiments of the present inventions have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter recited. For example, elements shown as integrally formed may be constructed of multiple parts or elements show as multiple parts may be integrally formed, the operation of the interfaces may be reversed or otherwise varied, the length or width of the structures and/or members or connector or other elements of the system may be varied, the nature or number of adjustment positions provided between the elements may be varied (e.g. by variations in the number of engagement slots or size of the engagement slots or type of engagement). It should be noted that the elements and/or assemblies of the system may be constructed from any of a wide variety of materials that provide sufficient strength or durability, in any of a wide variety of colors, textures and combinations. Accordingly, all such modifications are intended to be included within the scope of the present inventions. Other substitutions, modifications, changes and omissions may be made in the design, operating conditions and arrangement of the preferred and other exemplary embodiments without departing from the spirit of the present inventions.

### REFERENCES

[1] William Shockley and Hans J. Queisser, “Detailed Balance Limit of Efficiency of P-N Junction Solar Cells”, Journal of Applied Physics, Vol. 32 (March 1961)
[2] Einstein, Albert, “Über einen die Erzeugung und Verwandlung des Lichtes betreffenden heuristischen Gesichtspunkt”. Annalen der Physik 17: 132-148. (1905)
[3] Terman, F. E, et al, “Electronics and Radio Engineering.”, Page 23, 1955, McGraw Hill.
[4] Van Zeghbroeck, Bart J., “Mobility, Resistivity, and Sheet Resistance”, Section 2.9.2, 1997, University of Colorado.

### Notes

Overall conversion efficiency relates to the energy produced by the cell divided by the energy in the atmospheres optical window of the earth at sea level.

Conversion efficiency (or rate) relates to the electrons produced by the cell divided by the photons that enter the cell with energies higher than bandgap voltage of the materials used.

What is claimed is:

1. A solar cell comprising:
a p-type doped semiconductor material;
an n-type doped semiconductor material laterally adjacent to the p-type material, the p-type material and n-type material forming a stripped structure with finite depth, and forming a vertically structured diode at the junction of the p-type material and n-type material;
wherein the vertically structured diode has its depth determined by a multiple of an electromagnetic skin depth of at least one of the p-type material or n-type material and a width of a depletion layer is controlled by a doping concentration of the p-type and n-type material.

2. The solar cell of claim 1, wherein the diode has a depth spanning between the p-type material and the n-type material of at least three skin depths of the p-type material.

3. The solar cell of claim 2, wherein the diode has a depth of approximately 10 micrometers.

4. The solar cell of claim 1, wherein the width of the depletion layer comprises a width of at least ¼ of the longest wavelength of incoming light expected by the solar cell.

5. The solar cell of claim 4, wherein the depletion layer width is approximately 300 nanometers.

6. The solar cell of claim 1, wherein the depletion layer width is controlled by voltage that appears across the solar cell.

7. The solar cell of claim 1, further comprising a refractory material forming an optical element on a sun facing surface of the solar cell.

8. The solar cell of claim 7, wherein the optical element has a radius of curvature ranging from 1 to 2 micrometers.

9. A solar cell comprising:
a first region formed of a p-type semiconductor material;
a second region formed of an n-type semiconductor material;
a vertically structured photodiode between the first region and second region having a depth determined by a multiple of an electromagnetic skin depth of at least one of the p-type material or n-type material and width of a depletion region controlled by a doping concentration of the p-type and n-type material; and
a refractory material forming an optical element on a sun facing surface of the solar cell adapted to direct photons to a depletion region of the vertically structured photodiode.

10. The solar cell of claim 9, wherein the first region substantially surrounds the second region of semiconductor material forming a pocket of the second region of semiconductor material.

11. The solar cell of claim 9, further comprising a sidewall on an electric contact having a reflective surface directing low angle of incidence photons toward the photodiode.

12. The solar cell of claim 9 in which a plurality of solar cells are assembled to form an array.

13. The solar cell of claim 9 in which a plurality of solar cells are connected in series forming an isolated structure.

14. The solar cell of claim 9 in which a plurality of solar cells are connected in parallel.

15. The solar cell of claim 9, wherein a plurality of solar cells are connected in series-parallel structure so as to generate a higher cell voltage at a lower current.

16. The solar cell of claim 9, wherein the photodiode has a depth spanning between the p-type material and the n-type material of at least three skin depths of the p-type material.

17. The solar cell of claim 9, further comprising a depletion layer, wherein the width of the depletion layer comprises a width of at least ¼ of the longest wavelength of incoming light expected by the solar cell.

18. The solar cell of claim 9, wherein the optical element has a radius of curvature ranging from 1 micrometer to 2 micrometers.
